(19) United States
(12) Patent Application Publication
(10) Pub. No.: US 2002/0036345 A1
(43) Pub. Date: Mar. 28, 2002

(54) High frequency flip chip module and assembling method thereof

(75) Inventors: Yuji Iseki, Kanagawa (JP); Naoko Ono, Tokyo (JP); Keiichi Yamaguchi, Kanagawa (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: KABUSHIKI KAISHA TOSHIBA, Tokyo (JP)

(21) Appl. No.: 09/960,338

(22) Filed: Sep. 24, 2001

(30) Foreign Application Priority Data
Sep. 27, 2000 (JP) P2000-294053

(51) Int. Cl. H01L 23/48; H01L 23/52; H01L 29/40; H01L 47/00

(52) U.S. Cl. 257/734

(57) ABSTRACT

The semiconductor device embraces a module substrate; a plurality of substrate-cite interconnects disposed on the first main surface of the module substrate; a semiconductor chip mounted with the flip chip configuration; a plurality of joints connected to the substrate-cite interconnects; a circuit board; a plurality of board-cite interconnects disposed on the top surface of the circuit board, each being connected to one of the joints; and a first heat conductive material thermally connecting the bottom surface of the semiconductor chip with the top surface of the circuit board.

### CROSS REFERENCE TO RELATED APPLICATIONS

This application claims benefit of priority under 35 USC 119 based on Japanese Patent Application No. P2000-294053 filed Sep. 27, 2000, the entire contents of which are incorporated by reference herein.

### BACKGROUND OF THE INVENTION

1. Field of the Invention

The present invention relates to an assembling technology of a semiconductor device, more particularly to a semiconductor device for high frequency operation.

2. Description of the Related Art

Recently, corresponding to remarkable development of miniaturization and high frequency operation of cellular phone, modular high frequency circuit is becoming indispensable. Then, architecture of the flip chip (facedown) configuration is becoming popular in place of the face-up architecture. In the face-up architecture, a semiconductor chip is mounted on a module substrate with the orientation such that the top surface at which the active elements are merged, such as the high frequency transistors, is positioned at uppermost level, and electrical connections are made by gold wires to the bonding pads disposed on the top surface. In the flip chip architecture, the top surface at which the active elements are integrated is mated to the top surface of the module substrate, and the semiconductor chip is electrically connected to the module substrate by microelectrodes termed as “bumps”.

Length of the gold wires are required to be at least about 200 μm to make sure the electrical connection in the face-up architecture. On the contrary, the bumps in the flip chip architecture can be made thinner than 100 μm, resulting in very small parasitic capacitance and inductance generated therein. Therefore, it can be said that the flip chip architecture is more suitable mounting methodology to higher frequency operation than the face-up architecture. However, there is some problem on heat dissipation in the flip chip architecture. Most of the heat generated at the element on semiconductor chip is emitted to the module substrate via bump electrodes near semiconductor chip so that the heat resistance becomes high unless a special scheme is taken. Hence, heat dissipation performance is wrong than the face-up architecture, in which the heat dissipates directly via module substrate.

In order to improve such a problem on the heat dissipation, a structure shown in FIG. 1, for example, is proposed in Japanese Provisional Publication No. 169869 of 1995. In FIG. 1, a semiconductor chip 1 is assembled with a flip chip configuration via bump electrodes 93a, 93b, . . . , 93f attached on a module substrate 92. A lid 94 is connected to the module substrate 92 in the peripheral portion and also as a heat dissipating plate. A heat conductive material 95 is inserted between the lid and the semiconductor chip 1. The heat generated in the semiconductor chip 1 is conducted to the lid 94 via the heat conductive material 95 and emitted directly to the space by radiation. A Part of the heat dissipates to the module substrate 92 by thermal conduction.

### SUMMARY OF THE INVENTION

There was a problem that desired characteristics were not obtained due to insufficient heat dissipation when the high frequency module shown in FIG. 1 was applied to a miniaturized portable device. That is, in a miniaturized portable device, the heat dissipation is low when heat generated in the case is emitted by radiation, as the circulation of air between inside and outside of the case is insufficient. For such a miniaturized portable device, a heat transfer path such that the heat generated in the semiconductor chip on the module is conducted to the case through circuit board by heat conduction and then emitted to outer space from the case by radiation is more effective.

The present invention is made in consideration of above-mentioned circumstances, and an object of the present invention is to provide a semiconductor device having excellent heat dissipation characteristics.

In order to achieve the object, a first aspect of the present invention lies in a semiconductor device embracing (a) a module substrate having a first main surface and a second main surface facing with the first main surface; (b) a plurality of substrate-cite interconnects disposed on the first main surface; (c) a semiconductor chip having top and bottom surfaces, being mounted with the flip chip configuration, configured such that the top surface of the semiconductor chip facing to the first main surface of the module substrate so as to be aligned with the substrate-cite interconnects; (d) a plurality of joints connected to the substrate-cite interconnects, respectively; (e) a circuit board having top and bottom surfaces; (f) a plurality of board-cite interconnects disposed on the top surface of the circuit board, each being connected to one of the joints; and (g) a first heat conductive material thermally connecting the bottom surface of the semiconductor chip with the top surface of the circuit board.

A second aspect of the present invention lies in a method of assembling a semiconductor device. The method encompasses (a) preparing a module substrate having the first main surface and the second main surface facing to the first main surface, a plurality of substrate-cite interconnects being formed on the first main surface; (b) forming bumps on each of end portions of the substrate-cite interconnects; (c) mounting a semiconductor chip by the flip chip configuration, facing a top surface thereof to the first main surface, configured such that bonding pads disposed on the top surface of the semiconductor chip contact respectively with the bumps; (d) forming a plurality of joints on other end portions of the substrate-cite interconnects, respectively; and (e) mounting the module substrate on a circuit board, configured such that the joints connect to corresponding board-cite interconnects disposed on a top surface of the circuit board, and thermally connecting a bottom surface of the semiconductor chip with the top surface of the circuit board.

Other and further objects and features of the present invention will become obvious upon an understanding of the illustrative embodiments about to be described in connection with the accompanying drawings or will be indicated in the appended claims, and various advantages not referred to herein will occur to one skilled in the art upon employing of the present invention in practice.

### BRIEF DESCRIPTION OF THE DRAWINGS

FIG. 1 is a cross sectional view of a comparative semiconductor device.

FIG. 2 is a cross sectional view of a semiconductor device according to a first embodiment of the present invention.

FIG. 3 shows a plan view of a high frequency module scheduled to constitute a semiconductor device according to a first embodiment of the present invention, showing a state before being mounted on the circuit board.

FIG. 4 is a cross sectional view taken on line IV-IV in FIG. 3.

FIGS. 5A to 5D illustrate cross sectional views showing the steps of assembling a semiconductor device according to the first embodiment of the present invention.

FIG. 6 is a cross sectional view of a semiconductor device according to a second embodiment of the present invention.

FIGS. 7A to 7E illustrate cross sectional views showing the steps of assembling a semiconductor device according to the second embodiment of the present invention.

FIG. 8 is a cross sectional view of a semiconductor device according to a third embodiment of the present invention.

FIG. 9 is a plan view showing a high frequency module constituting a semiconductor device according to the third embodiment of the present invention, showing a state before being mounted on the circuit board.

FIG. 10 is a cross sectional view taken on line X-X in FIG. 9.

FIGS. 11A to 11D illustrate cross sectional views showing the steps of assembling a semiconductor device according to the third embodiment of the present invention.

FIG. 12 is a cross sectional view of a semiconductor device according to a fourth embodiment of the present invention.

FIGS. 13A to 13F illustrate cross sectional views showing the steps of assembling a semiconductor device according to the fourth embodiment of the present invention.

FIG. 14 is a cross sectional view of a semiconductor device according to a modification of the fourth embodiment of the present invention.

FIG. 15 is a cross sectional view of a semiconductor device according to another modification of the fourth embodiment of the present invention.

FIG. 16 is a cross sectional view of a semiconductor device according to further different modification of the fourth embodiment of the present invention.

FIG. 17 is a cross sectional view of a semiconductor device according to a fifth embodiment of the present invention.

FIG. 18 is a cross sectional view of a semiconductor device according to a modification of the fifth embodiment of the present invention.

FIG. 19 is a cross sectional view of a semiconductor device according to another modification of the fifth embodiment of the present invention.

FIG. 20 is a cross sectional view of a semiconductor device according to further different modification of the fifth embodiment of the present invention.

FIG. 21 is a cross sectional view of a semiconductor device according to a sixth embodiment of the present invention.

FIG. 22 shows a plan view of a high frequency module constituting a semiconductor device according to the sixth embodiment of the present invention, showing a state before being mounted on the circuit board.

FIG. 23 is a cross sectional view taken on line XXIII-XXIII in FIG. 22.

FIGS. 24A to 24C illustrate cross sectional views showing the steps of assembling a semiconductor device according to the sixth embodiment of the present invention.

### DETAILED DESCRIPTION OF THE EMBODIMENTS

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified. Generally and as it is earlier in the representation of semiconductor devices, it will be appreciated that the various drawings are not drawn to scale from one figure to another nor inside a given figure, and in particular that the layer thicknesses are arbitrarily drawn for facilitating the reading of the drawings. In the following description specific details are set fourth, such as specific materials, process and equipment in order to provide thorough understanding of the present invention. It will be apparent, however, to one skilled in the art that the present invention may be practiced without these specific details. In other instances, well-known manufacturing materials, process and equipment are not set fourth in detail in order not unnecessary obscure the present invention. Prepositions, such as “on”, “over” and “above” are defined with respect to a planar surface of the substrate, regardless of the orientation the substrate is actually held. A layer is on another layer even if there are intervening layers.

(First Embodiment)

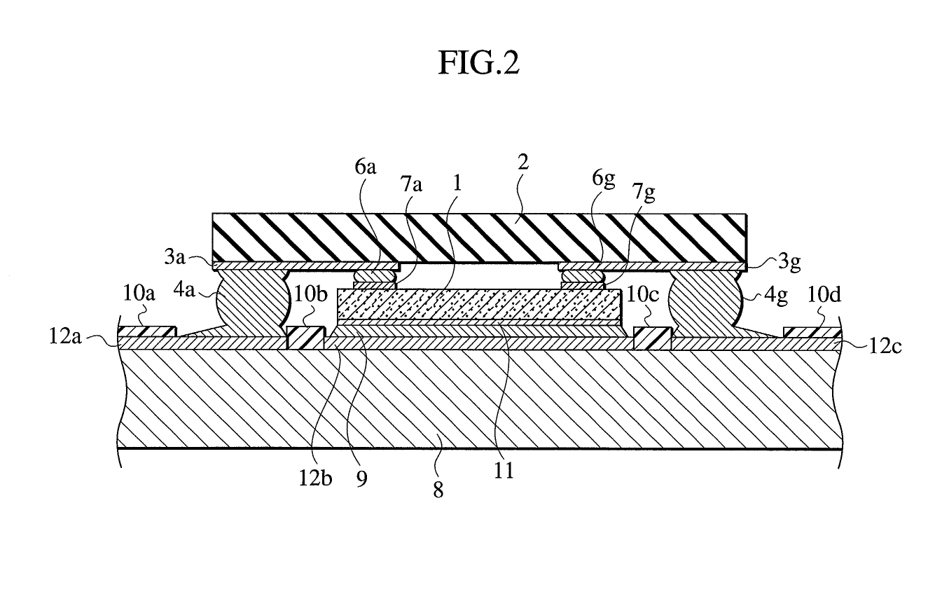

As shown in FIG. 2, a semiconductor device according to a first embodiment of the present invention has a plurality of substrate-cite interconnects 3a, . . . 3g, . . . formed on a first main surface of a module substrate 2, a semiconductor chip 1 mounted on a module substrate 2 by a flip chip architecture via a plurality of substrate-cite interconnects 3a, . . . , 3g, . . . , a plurality of ball electrodes serving as joints 4a, . . . , 4g, . . . , connected with the substrate-cite interconnects 3a, . . . , 3g, . . . , a circuit board 8 having, at the top surface, a plurality of board-cite interconnects 12a,12c, . . . , each connected to the joints 4a, . . . , 4g, . . . , and a first heat conductive material 9 thermally connecting a bottom surface of the semiconductor chip 1 with a top surface of the circuit board 8. Here, the module substrate 2 has the first and the second main surfaces. The second main surface is a main surface facing to the first main surface of the substantially slab-shaped module substrate 2. That is, it can be considered that either the first or the second main surface is the top surface and another is the bottom surface. As described already, the flip chip architecture mounts the semiconductor chip 1 with the orientation, in which the top surface of the semiconductor chip 1 is mated to the first main surface of the module substrate 2 using bumps 6a, . . . , 6g, . . . . Here, the top surface of the semiconductor chip 1 is the main surface at the side where an active element region (active area) is formed thereon. The active element region is the region where a semiconductor active element such as a field effect transistor (FET), a high electron mobility transistor (HEMT), a heterojunction bipolar transistor (HBT) is defined thereon. These semiconductor elements such as FET, HEMT, and HBT are formed on the top surface of the semiconductor chip 1 by micro fabrication technology such as the photolithography method. As will be clarified by the fourth embodiment described later, a transmission line and other passive elements are also formed in the “active element region ”.

On the peripheral region of the top surface of the semiconductor chip 1, bonding pads 7a, . . . , 7g, . . . are formed and by connecting thereto bumps 6a, . . . , 6g, . . . , the bonding pads 7a, . . . , 7g, . . . are electrically connected to substrate-cite interconnects 3a, . . . , 3g. . . . On the bottom surface of the semiconductor chip 1, a back electrode 11 is formed. In a region facing to the semiconductor chip 1, and on the surface of the circuit board 8, a heat-transfer interconnect 12b is formed. That is, connecting the heat-transfer interconnect 12b to the back electrode 11, using the first heat conductive material 9, thermally connects the bottom surface of the semiconductor chip 1 to the top surface of the circuit board 8.

In the first embodiment, a tin-lead solder with a ratio of tin (Sn) to lead (Pb) of 6:4 is used for the first heat conductive material 9. A solder with Sn:Pb=5:95 can also be used. The tin-lead solder is also used for the joints (ball electrode) 4a, . . . , 4g, . . . . The diameter of the joints (ball electrodes ) 4a, . . . , 4g, . . . are from 100 μm to 350 μm and the heights are from 50 μm to 300 μm, approximately. Solder resists 10a, 10b, 10c, 10d, . . . are disposed between the board-cite interconnects 12a, 12c, . . . each other on the circuit board 8 and between the board-cite interconnects 12a, 12c, . . . and that for heat conduction use 12b. In the solder reflow process, molten solder flows onto the board-cite interconnects 12a, 12c, . . . , and further flows onto the heat-transfer interconnect 12b on the circuit board 8, in the spaces defined by the solder resist 10a, 10b, 10c, 10d, . . . . Then, the board-cite interconnects 12a, 12c, . . . and the heat-transfer interconnect 12b are respectively selectively wet by the molten solder, without requiring any special and complicated process.

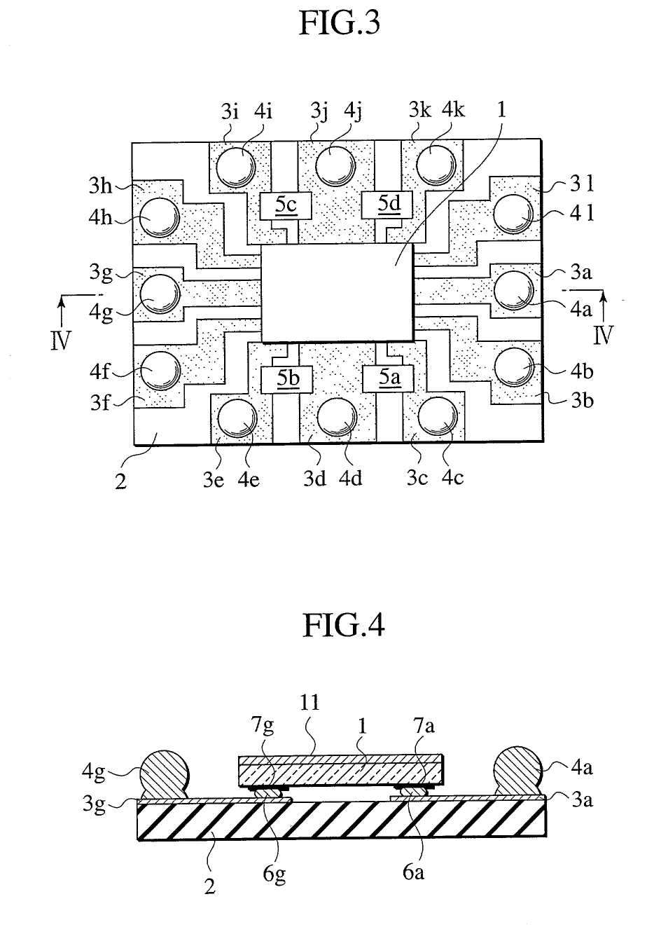

FIG. 3 is a plan view of a high frequency module (module substrate) 2 constituting a semiconductor device according to the first embodiment of the present invention. That is, it shows a plan view of the high frequency module before being mounted on the circuit board 8 shown in FIG. 2. In the high frequency module according to the first embodiment of the present invention, a plurality of substrate-cite interconnects 3a, 3b, . . . , 3g, . . . are disposed almost in a radial manner on a first main surface of the module substrate 2 as shown in FIG. 3. A semiconductor chip 1 is mounted by a flip chip architecture on the mounting region in a central portion of the module substrate 2 where the substrate-cite interconnects 3a, 3b, . . . , 3g, . . . are concentrated. Each of the edge portions of the substrate-cite interconnects 3a, 3b, . . . , 3g, . . . on the side close to a peripheral region of the module substrate 2 is patterned to rectangular shape to form lands. On each of these lands, the joints (ball electrodes ) 4a, 4b, . . . , 4g, . . . are disposed. Further, on the first main surface of the module substrate 2, chip-shaped circuit components 5a, 5b, 5c, 5d, . . . serving as passive elements such as capacitor and resistor are also mounted.

FIG. 4 is a plan view taken on line IV-IV in FIG. 3, showing that the semiconductor chip 1 is assembled with flip chip architecture by the bumps 6a, . . . , 6g, . . . on the first main surface of the module substrate 2. In the high frequency module according to the first embodiment, gallium arsenide (GaAs) is used for the semiconductor chip 1. The GaAs chip 1 is polished thinly to about 150 μm. Further, in the first embodiment, a metallic film composed of single metal such as gold-germanium alloy (Au—Ge), titanium (Ti), gold (Au), nickel (Ni), palladium (Pd), platinum (Pt), molybdenum (Mo), tungsten (W), aluminum (Al) or a laminated structure by combination of more than two of these metals is formed on bottom surface of the semiconductor chip 1 as the back electrode 11. On the top surface of the semiconductor chip 1 opposing to the back electrode 11, bonding pads 7a, . . . , 7g, . . . composed of metallic film such as Al, Au and aluminum alloy (Al—Si, Al—Cu—Si) are formed. On each of these bonding pads 7a, . . . , 7g, . . . , bumps 6a, . . . , 6g, . . . are disposed to be mounted on the module substrate 2 by the flip chip configuration. A stud bumps made of gold (Au) are used for the bumps 6a, . . . , 6g, . . . . Besides gold bump, silver (Ag) bump, copper (Cu) bump, nickel-gold (Ni—Au) bump and nickel-gold-indium (Ni—Au—In) bump and another material can be used.

A plurality of bonding pads 7a, . . . , 7g, . . . are each connected to for example, a plurality of high impurity concentration region (source/drain regions or emitter/collector regions) doped with about 1×10¹⁸ cm⁻³˜1×10²¹ cm⁻³ donors or acceptors formed in the active element region at the top surface of the semiconductor chip 1. The ohmic electrode layers made of metals such as titanium/platinum/gold (Ti/Pt/Au), titanium/platinum/nickel/gold (Ti/Pt/Ni/Au) and gold-germanium alloy (Au—Ge) are metallurgically contacted to these plural high impurity concentration regions. On the upper portion of these plural ohmic electrode layers, a passivation film made of, for example, a silicon oxide film (SiO₂), a phosphosilicate glass (PSG) film, a boro-phosphosilicate glass (BPSG) film, a silicon nitride film (Si₃N₄), or a polyimid film is formed. And a plurality of aperture (window) portions are provided in the passivation film, the plural electrode layers being deposited thereon, and the bonding pads 7a, . . . , 7g, . . . are constructed.

Or, such a multi-level interconnection structure may be used that an interlayer insulating film made of SiO₂, PSG or BPSG films is formed on the ohmic electrode layers, providing via holes (window portions) in the interlayer insulating film, and connecting the metallic pads such as Al, aluminum alloy (Al—Si, Al—Cu—Si), Au and Cu to the ohmic electrode layers through contact plugs buried in the via holes. In this case, on the uppermost metallic pads, the passivation film made of the SiO₂ film, PSG film, BPSG film, Si₃N₄ film or polyimid film is formed, and a plurality of rectangular aperture (window) portions are formed to expose the uppermost metallic pads, and thus a plurality of bonding pads can be arranged. In this way, the bonding pads 7a, . . . , 7g, . . . may be formed as different level metallic patterns, each connected to the ohmic electrode layers through a plurality of metallic interconnects. In the case of, for example, MISFET, the bonding pads 7a, . . . , 7g, . . . made of metal such as Al or aluminum alloy (Al—Si, Al—Cu—Si) can be stacked on a gate electrode composed of metals such as Al, W, Ti and Mo and silicide of refractory metals (WSi₂, TiSi₂, MoSi₂). Other plural bonding pads 7a,. . . , 7g, . . . can also be electrically connected, through a plurality of signal lines such as gate wiring lines, to a plurality of gate electrodes.

As shown in FIG. 4, the semiconductor chip 1 is attached (mounted) on the first main surface of the module substrate 2 with the face down configuration, in which the top surface is faced downward, at the top surface the integrated circuit is merged. These bonding pads 7a,. . . , 7g, . . . are not necessary to be disposed in the peripheral region of the semiconductor chip 1. Height of the bumps after being mounted on the module substrate 2 is about 30 μm. For capacitor chip, which is generally the thickest chip among the circuit chip 5a, 5b, 5c, 5d, a ceramic capacitor with single slab plate having electrode on the same surface, for example, 113 TWIN/CAP of American Technical Ceramics Corp. is used. This capacitor is mounted on the module substrate 2 using gold stud bump for mounting the semiconductor chip. For the joints (ball electrodes) 4a, . . . , 4g, . . . , a solder material, which is also widely used for assembling the Si chip, is employed. An alumina (Al₂O₃) of 200 μm thick is used for the module substrate 2. The constituent materials of interconnects 3a, 3b, . . . , 3g, . . . formed on the substrate are Ti/Ni/Au.

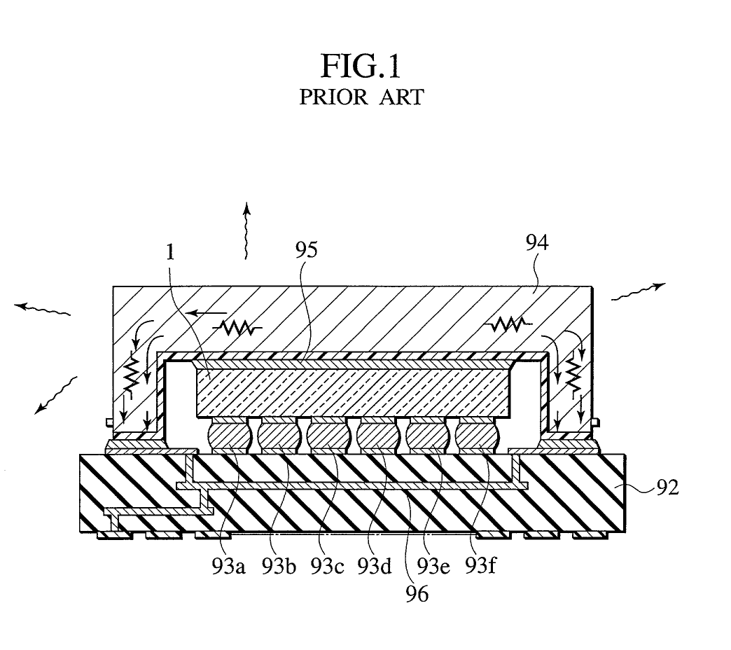

By the semiconductor device shown in FIG. 2 according to the first embodiment of the present invention, heat generated in the active element region (active area) is transported by heat conduction through a heat transfer path, routing in order of the bottom surface of the semiconductor chip 1, the metallic film (back electrode) 11 formed on the bottom surface of the chip, the solder 9, board-cite interconnects 12a, 12c, . . . on the circuit board 8 and the circuit board 8, to the circuit board 8, from which the heat is dissipated to the surrounding ambient by radiation. The heat can also be dissipated by heat conduction to the motherboard, the backplane, the case or the equipment drawer, to which the circuit board 8 is connected. Thus, in the semiconductor device according to the first embodiment of the present invention, the bottom surface of the flip chip mounted semiconductor chip 1 is thermally contacted with the top surface of the circuit board 8 through the first heat conductive material 9. Hence, heat dissipation through low heat resistance is possible. For example, in the comparative structure shown in FIG. 1, the heat resistance was 63.2° C./W for the case of using the semiconductor chip (GaAs chip) 1 of 500 μm thick, the lid 94 by copper plate of 100 μm thick and the heat conductive material 95 by a resin adhesive with high thermal conductivity. On the contrary, the heat resistance of the semiconductor device according to the first embodiment of the present invention is 54.8° C./W, in which a lead-tin solder is in contact with the back electrode 11 of the semiconductor chip (GaAs chip ) 1 of 150 μm thick, resulting in a higher heat dissipation performance.

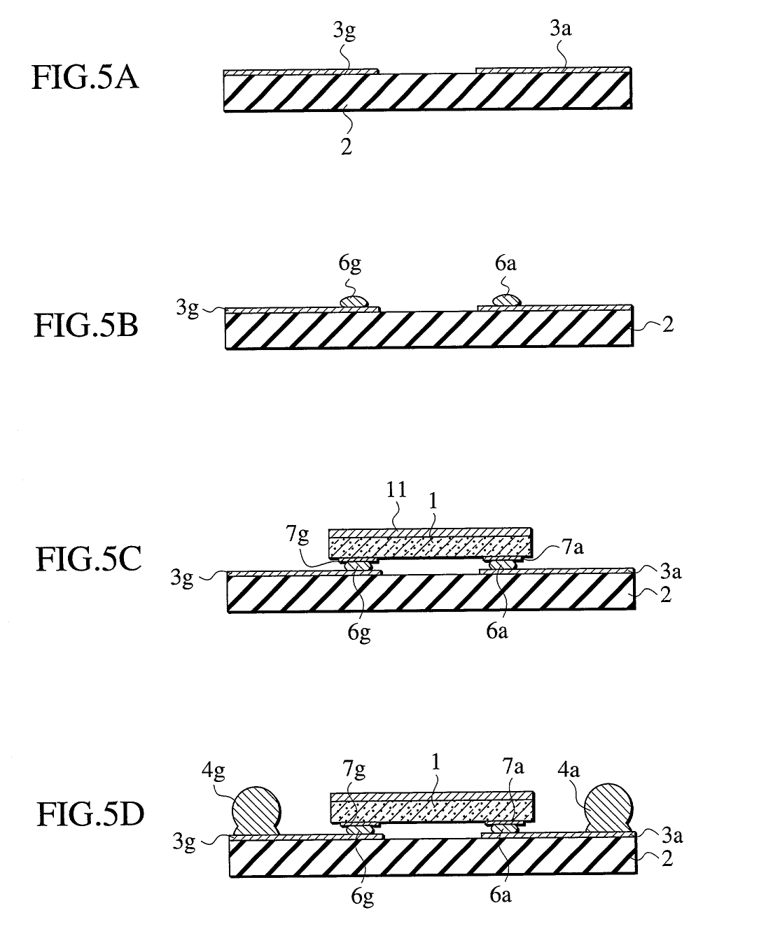

Next, a method of assembling the semiconductor device according to the first embodiment of the present invention will be described using FIGS. 5A to 5D.

(a) First, the module substrate 2, on the first main surface of which the substrate-cite interconnects 3a, . . . , 3g, are formed, is prepared as shown in FIG. 5A.

(b) Next, bumps 6a, . . . , 6g, . . . made of gold (As) are formed near one end of the substrate-cite interconnects 3a, . . . , 3g, . . . as shown in FIG. 5B.

(c) The semiconductor chip 1 is mounted with the flip chip configuration on the first main surface of the module substrate 2 via bumps 6a, . . . , 6g, . . . as shown in FIG. 5C. At this time, the bumps 6a, . . . ,6g, . . . are each connected to bonding pads 7a, . . . , 7g, . . . arranged in the peripheral region on the top surface of the semiconductor chip 1.

(d) As shown in FIG. 5D, in the neighborhood of other end portions of the substrate-cite interconnects 3a, . . . , 3g, . . . , ball electrodes 4a, . . . 4b, . . . , 4g, . . . serving as the joints are each formed. For the ball electrodes 4a, . . . 4b, . . . ,4g, . . . , for example, tin-lead solders having the diameter of 300 μm are used.

(e) On the other hand, patterns of solder resists 10a, 10b, 10c, 10d are delineated on the circuit board 8 using photolithography as shown in FIG. 2. Further, the first heat conductive material 9 is printed (coated) on the heat-transfer interconnect 12b on the circuit board 8 using a screen-printing process. The tin-lead solder having the same melting point as the joints (ball electrode) 4a, . . . , 4g, . . . can also be used for the first heat conductive material 9. The circuit board 8 is so positioned relative to the module substrate 2 that the joints (ball electrodes) 4a, . . . ,4g, . . . are located on the end portion of the board-cite interconnects 12a, 12c, . . . of the circuit board 8 and then the module substrate 2 is mounted on the circuit board 8 to construct a packaged assembly mounting the module.

(f) Thereafter, putting the packaged assembly into an electrical oven, a heat treatment for solder reflow is carried out. As the patterns for solder resists 10a, 10b, 10c and 10d are defined on the circuit board 8, the molten solders flow onto the heat-transfer interconnect 12b and the board-cite interconnects 12a, . . . 12c, . . . on the circuit board 8. Therefore, the bottom surface of the semiconductor chip 1 is wet with the solder, delineated by the printing process, molten on the surface of the heat-transfer interconnect 12b on the circuit board 8. As a result, the bottom surface of the semiconductor chip 1 is thermally connected with the top surface of the circuit board 8 through the tin-lead solder, or the first heat conductive material 9. At the same time, the board-cite interconnects 12a, 12c, . . . on the circuit board 8 and the corresponding bonding pads 7a, . . . , 7g, . . . on the top surface of the semiconductor chip 1 are electrically connected each other through the respective joints (ball electrodes) 4a, . . . , 4g, . . . , and the semiconductor device according to the first embodiment of the present invention shown in FIG. 2 is completed.

(Second Embodiment)

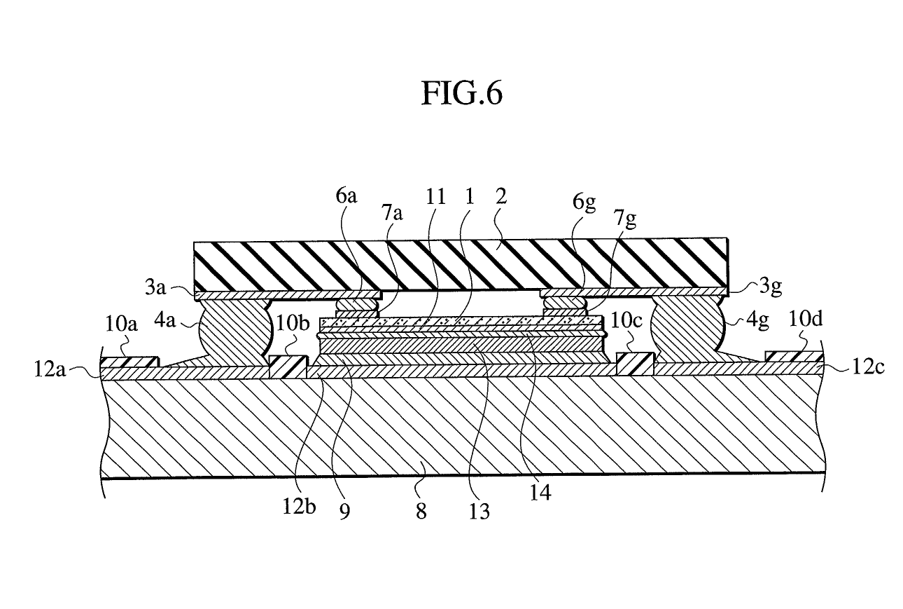

As shown in FIG. 6, a semiconductor device according to a second embodiment of the present invention encompasses, similarly to the first embodiment, the module substrate 2, the semiconductor chip 1 mounted on the module substrate 2, and the circuit board 8 mounting the module substrate 2. A plurality of substrate-cite interconnects 3a, . . . , 3g, . . . are formed on the first main surface of the module substrate 2. The semiconductor chip 1 is mounted with the flip chip configuration on the module substrate 2 via the substrate-cite interconnects 3a, . . . , 3g, . . . . A plurality of ball electrodes serving as the joints 4a, . . . , 4g, . . . are respectively connected to the substrate-cite interconnects 3a, . . . , 3g, . . . . The circuit board 8 has, on the top surface, a plurality of board-cite interconnects 12a, 12c, . . . connected each to the joints (ball electrodes) 4a, . . . , 4g, . . . . The first heat conductive material 9 is thermally connecting the bottom surface of the semiconductor chip 1 with the top surface of the circuit board 8. A plurality of bonding pads 7a, . . . , 7g, . . . are formed on the peripheral region on the top surface of the semiconductor chip 1. The bonding pads 7a, . . . , 7g, . . . are connected to bumps 6a, . . . , 6g, . . . , so that the bonding pads 7a, . . . , 7g, . . . are electrically connected to the substrate-cite interconnects 3a, . . . , 3g, . . . . On the bottom surface of the semiconductor chip 1, the back electrode 11 is formed. And, on the top surface of the circuit board 8, facing to the semiconductor chip 1, a heat-transfer interconnect 12b is formed. That is, the bottom surface of the semiconductor chip 1 and the top surface of the circuit board 8 is thermally connected by connecting the heat-transfer interconnects 12b with the back electrode 11 through the first heat conductive material 9. In the second embodiment, tin-lead solder is also used for the first heat conductive material, similarly to the first embodiment. For the joints (ball electrodes ) 4a, . . . , 4g, . . . , the tin-lead solder is also used.

Particularly, the semiconductor device according to the second embodiment of the present invention has a heat conductive plate 13 in contact with the first heat conductive material 9, and a second heat conductive material 14 in contact with the heat conductive plate 13. The second heat conductive material 14 is disposed on the heat conductive plate 13. The stacked structure made of the second heat conductive material 14 and the heat conductive plate 13 forms the heat transfer path from the bottom surface of the semiconductor chip 1 to the first heat conductive material 9. Other structure and materials are similar to the structure and materials already explained in the first embodiment, and the overlapped description or the redundant description is omitted in the second embodiment. Namely, the plan view is omitted, as it is essentially similar to FIG. 3, used for the description of the first embodiment.

As the semiconductor device, according to the second embodiment of the present invention, is capable of using a thinner semiconductor chip 1, the heat resistance can be lowered further and an excellent heat dissipation performance is obtained. As above-mentioned, in the case of using the tin-lead solder for the first heat conductive material 9, a gold-tin solder having a higher melting point can be used for the second heat conductive material 14. Further, for the heat conductive plate 13, a ceramics substrate having high thermal conductivity such as aluminum nitride (AlN) and beryllia (BeO). Or a structure of metal plate such as kovar (Fe—Ni—Co—alloy), with a specific metallization treatment on the surface, can also be used as the heat conductive plate 13. Generally, the thermal conductivity of the semiconductor chip 1 is far lower than those of the first and the second heat conductive materials 14 and the heat conductive plate 13. Therefore, entire heat resistance can be lowered by making the semiconductor chip 1, having low thermal conductivity, thinner by polishing, and the reduced thickness is adjusted by the second heat conductive material 14 and the heat conductive plate 13. And, as the gold-tin solder has higher thermal conductivity than the tin-lead solder, the heat dissipation performance becomes excellent. As previously described, for the case of contacting the tin-lead solder with the back electrode 11 on GaAs chip of 150 μm thick in the first embodiment, the heat resistance was 54.8° C./W. For the case of the structure, in which the GaAs chip 1 has been thinned to 70 μm and the gold-tin solder is in contact with the back electrode 11, configured such that the heat is dissipated through the heat conductive plate 13 made of aluminum nitride of 100 μm thick, the heat resistance is 53.1° C./W, resulting in an improvement of the heat dissipation performance.

Though the mechanical strength is lowered when the semiconductor chip 1 is thinned, sufficient strength can be maintained by the function of the heat conductive plate 13 as a reinforcement material. Further, if the effective height of the semiconductor chip 1 is maintained at a desired level by thickness adjustment through the heat conductive material 14 and the heat conductive plate 13, relatively thick passive element (chip-shaped circuit component) can also be mounted on the same first main surface as the semiconductor chip 1. That is, effective height of the semiconductor chip 1 can easily be adjusted to a desired height without increasing the heat resistance. Therefore, it is not necessary to adopt such a special configuration as described in the first embodiment for the chip-shaped circuit components 5a, 5b, and 5c. For example, so-called general-purpose component of surface mounting type, such as a laminated ceramics capacitor GRM33 series (outer size; 0.6 mm×0.3 mm×0.3 mm) of Murata Manufacturing Co. Ltd., can be used for the chip-shaped circuit components 5a, 5b, 5c, and 5d. Therefore the production cost is lowered and the industrial/commercial profit is large.

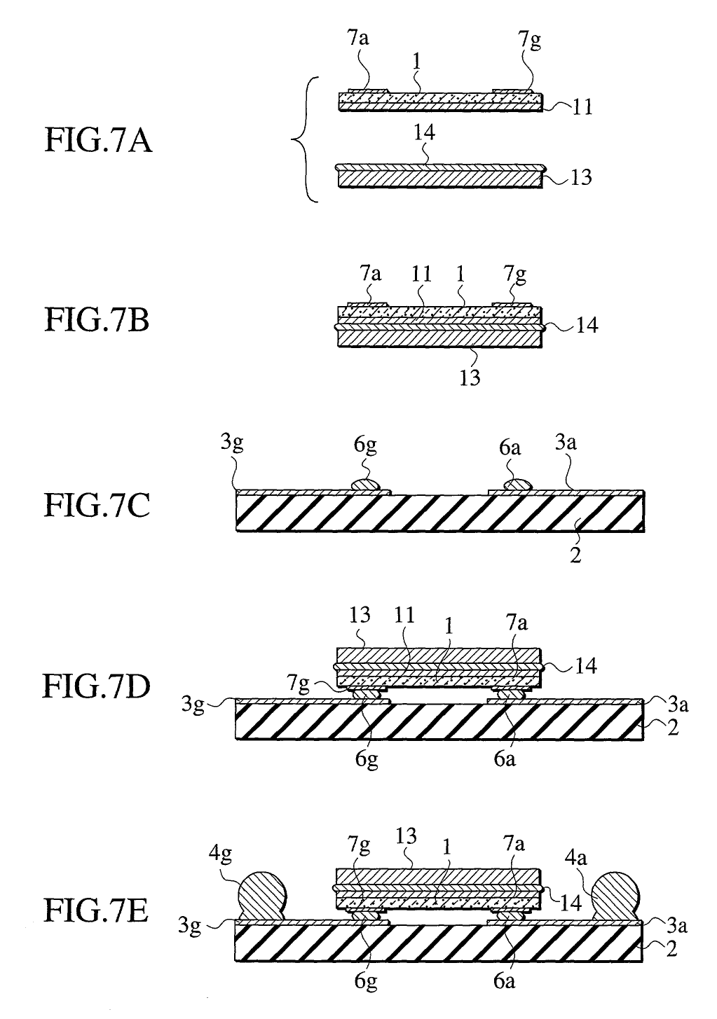

Next, the method of assembling the semiconductor device according to the second embodiment of the present invention will be described using FIGS. 7A to 7E.

(a) First, the semiconductor chip 1 is polished to the substrate thickness of 30 μm˜100 μm. Preferably, the substrate thickness should be 40 μm˜10 μm. Though the heat dissipation performance is improved for the thickness of the semiconductor chip 1 below 30 μm, the handling of the semiconductor chip 1 becomes so difficult that mechanical damage is easily introduced and productivity is lowered. The back electrode 11 is formed on the bottom surface of the semiconductor chip 1 as shown in FIG. 7A. A chemical etching may be done before forming the back electrode 11 for elimination of the damages due to the polishing process. On the one hand, the heat conductive plate 13 such as aluminum nitride substrate of about 70-150 μm in thickness is prepared separately. Over the entire surface of one of the main surfaces of heat conductive plate 13, the gold-tin solder is formed as the second heat conductive material 14 as shown in FIG. 7A.

(b) Next, the semiconductor chip 1 and the heat conductive plate 13 are mated together so that the second heat conductive material 14 is in contact with the back electrode 11 of the semiconductor chip 1. Then the semiconductor chip 1 is bonded to the heat conductive plate 13 by allowing the gold-tin solder 14 to reflow as shown in FIG. 7B.

(c) The module substrate 2 is prepared, on the first main surface thereof the substrate-cite interconnects 3a, . . . , 3g, . . . are formed. Further, the bumps 6a, . . . , 6g, . . . made of gold are formed near the one end portion of the substrate-cite interconnects 3a, . . . , 3g, . . . as shown in FIG. 7C.

(d) The semiconductor chip 1 is mounted with the flip chip configuration on the first main surface of the module substrate 2 via the bumps 6a, . . . , 6g, . . . as shown in FIG. 7D. At this time, the bumps 6a, . . . , 6g, . . . are each made to be connected to the bonding pads 7a, . . . , 7g, . . . formed on the peripheral region on the top surface of the semiconductor chip 1.

(e) As shown in FIG. 7E, ball electrodes 4a, 4b, . . . , 4g, . . . , serving as the joints, are each formed near another ends on the respective substrate-cite interconnects 3a, . . . , 3g, . . . . For the ball electrodes 4a, . . . 4b, . . . , 4g, . . . tin-lead solder of 300 μm in diameter, for example, is used. The following steps after the state shown in FIG. 7E are essentially the same as the method of assembling the semiconductor device according to the first embodiment, so that the repeated description will be omitted.

(Third Embodiment)

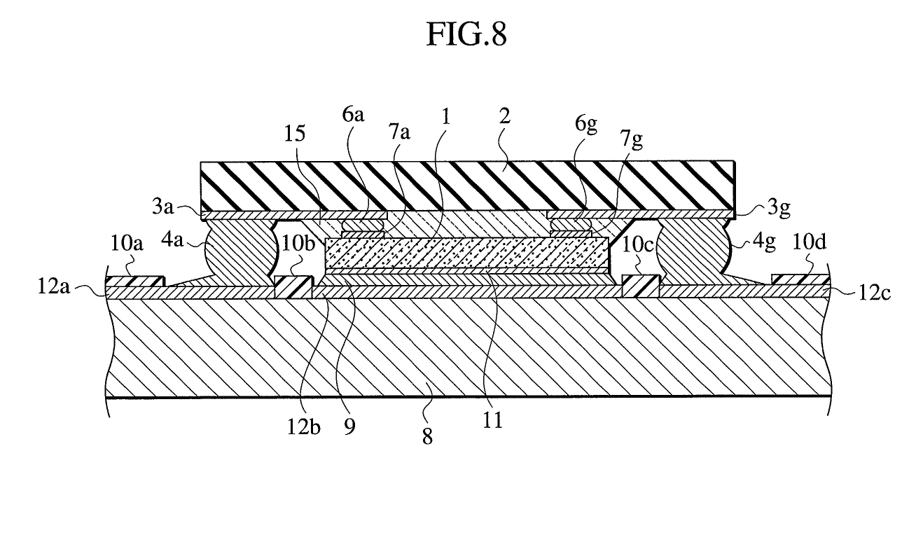

As shown in FIG. 8, a semiconductor device according to a third embodiment of the present invention encompasses, similarly to the first embodiment, the module substrate 2, the semiconductor chip 1 mounted on the module substrate 2, and the circuit board 8 mounting the module substrate 2. A plurality of the substrate-cite interconnects 3a, . . . , 3g, . . . are formed on the first main surface of the module substrate 2. The semiconductor chip 1 is mounted with the flip chip configuration on the module substrate 2 via the substrate-cite interconnects 3a, . . . , 3g, . . . . A plurality of ball electrodes serving as the joints 4a, . . . , 4g, . . . are connected to the substrate-cite interconnects 3a, . . . , 3g, . . . . The circuit board 8 has, on the top surface, a plurality of board-cite interconnects 12a, 12c, . . . connected each to the joints (ball electrodes) 4a, . . . , 4g, . . . . The first heat conductive material 9 is thermally connecting the bottom surface of the semiconductor chip 1 with the top surface of the circuit board 8.

Particularly, unlike the first embodiment, the semiconductor device of the third embodiment has a sealing resin 15 inserted additionally between the top surface of the semiconductor chip 1 and the first main surface of the module substrates.

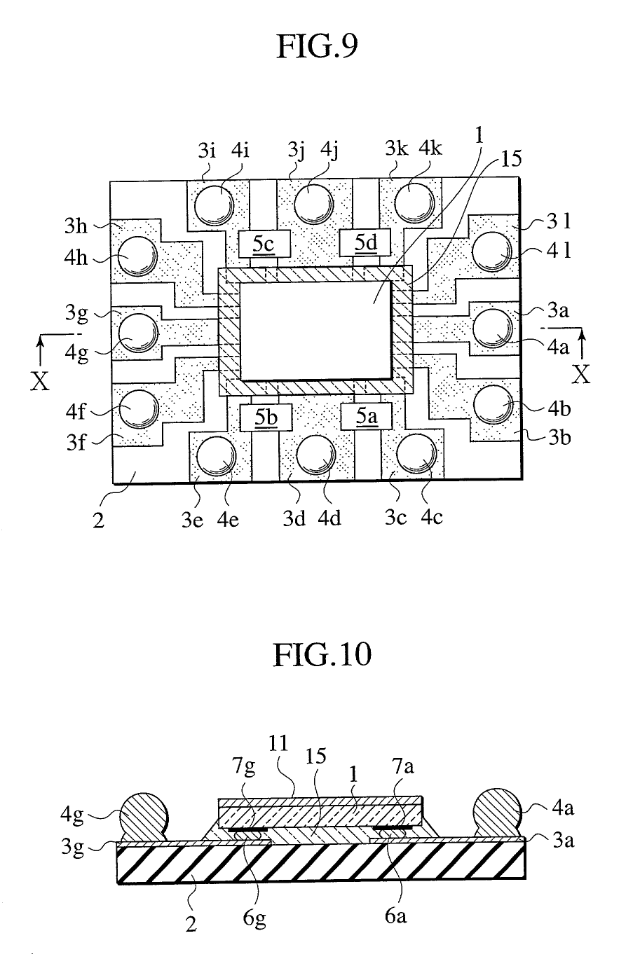

FIG. 9 shows a plan view of the high frequency module (module substrate) 2, or the semiconductor device of the third embodiment of the present invention. That is, it is the plan view of the high frequency module before being mounted on the circuit board 8 shown in FIG. 8. As shown in FIG. 9, the high frequency module according to the third embodiment has the substrate-cite interconnects 3a, 3b, . . . , 3g, . . . , . . . disposed on the first main surface approximately in a radial manner similarly to the first embodiment. The semiconductor chip 1 is mounted with the flip chip configuration in the central portion of the module substrate 2 to which the substrate-cite interconnects 3a, . . . 3b, . . . , 3g, . . . , . . . are concentrated. And, a part of the sealing resin 15 is exposed from the peripheral region of the semiconductor chip 1. Chip-shaped circuit components 5a, 5b, 5c and 5d serving as the passive elements, such as the capacitor and the resistor are also mounted on the first main surface of the module substrate 2 in the positions outside the sealing resin 15.

FIG. 10 is a cross-sectional view taken on line X-X in FIG. 9 and shows that the semiconductor chip 1 is mounted on the first main surface of the module substrate 2 by the flip chip architecture, in the configuration such that the top surface of the semiconductor chip 1, on which the integrated circuit is merged, facing downward to the module substrate 2. Height of the bumps 6a, . . . , 6g, . . . after being mounted on the module substrate 2 is about 30 μm. The sealing resin 15 is embedded into this gap of 30 μm between the semiconductor chip 1 and the module substrate 2, enclosing the bumps 6a, . . . , 6g, . . . . Other structure and materials are similar to those already explained in FIG. 2 to FIG. 4 used for the description of the first embodiment, and the overlapped description or the redundant description is omitted in the third embodiment.

According to the structure of the semiconductor device of the third embodiment, stress generated in the bumps 6a, . . . , 6g, . . . due to a difference in thermal expansion coefficient between the semiconductor chip 1 and the module substrate 2 can be relaxed by the sealing resin 15. Consequently, crack generation in the bumps 6a, . . . , 6g, . . . , due to various heat treatments during the assembling processes or due to heat generation associated with the operation of the semiconductor element after assembling process, is prevented, thereby improving the assembling reliability.

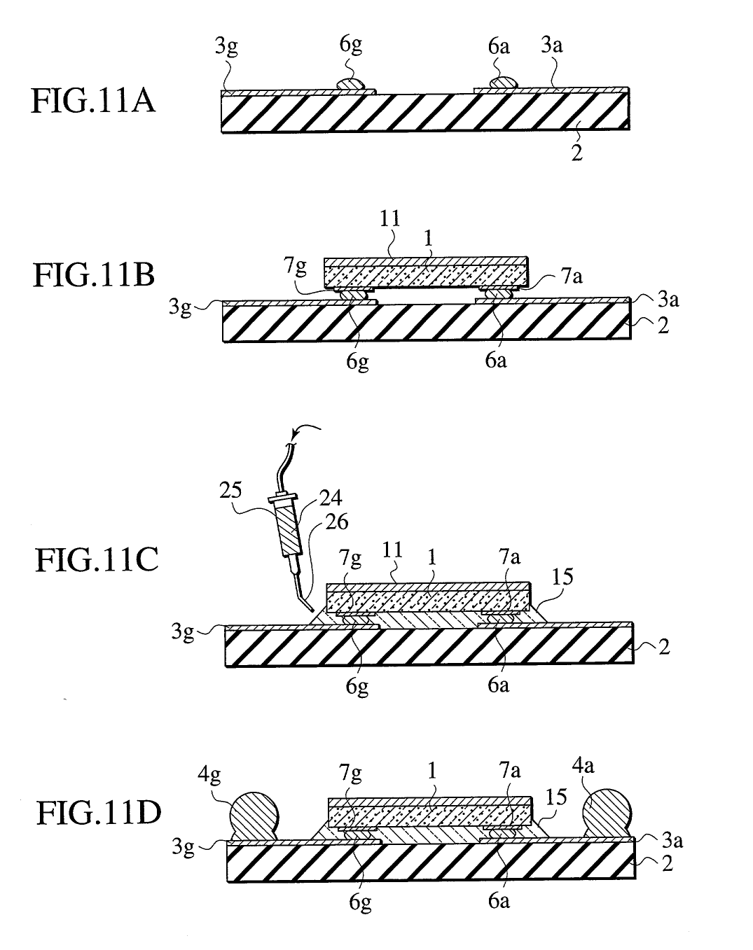

Next, the method of assembling the semiconductor device of the third embodiment will be described using FIGS. 11A to 11D.

(a) First, the module substrate 2 is prepared, on the first main surface of which the substrate-cite interconnects 3a, . . . , 3g, . . . are formed. Then the bumps 6a, . . . , 6g, . . . made of Au are formed in the neighborhood of the respective end portions of the substrate-cite interconnects 3a, . . . , 3g, . . . as shown in FIG. 1A.

(b) The semiconductor chip 1 is mounted by the flip chip architecture on the first main surface of the module substrate 2 via the bumps 6a, . . . , 6g, . . . as shown in FIG. 11B. At this time, the bumps 6a, . . . , 6g, . . . are made to be each connected to the bonding pads 7a, . . . 7g, . . . arranged on the peripheral surface region of the semiconductor chip 1.

(c) As shown in FIG. 11C, a paste-like liquid resin 24 contained in a syringe 25 is injected from a tip of a delivering needle 26 using gas pressures, such that the liquid resin 24 can flow from the peripheral region of the semiconductor chip 1 into the space between the semiconductor chip 1 and the module substrate 2. Then, the liquid resin 24 is solidified and a structure, inserting the sealing resin 15 between the semiconductor chip 1 and the module 2, is completed.

(d) As shown in FIG. 11D, the ball electrodes 4a, 4b, . . . , 4g, . . . are each formed as the joints on other ends of the substrate-cite interconnects 3a, . . . , 3g, . . . . The succeeding steps from the state shown in FIG. 11D are essentially the same as those for the method of assembling the semiconductor device according to the first embodiment, so that the repeated description will be omitted.

The process of molding, by sealing with resin 15 after connecting the semiconductor chip 1 to the module substrate 2 by the flip chip configuration is explained in the third embodiment. However, it is not only limited to this methodology. For example, the semiconductor chip 1 can be mounted with the flip chip configuration after coating the paste-like resin on the mounting region of the module substrate 2. The semiconductor chip 1 can be mounted with the flip chip configuration after sticking a sheet-like resin on the mounting region of the module substrate 2, in place of coating the paste-like resin on the module substrate 2.

(Fourth Embodiment)

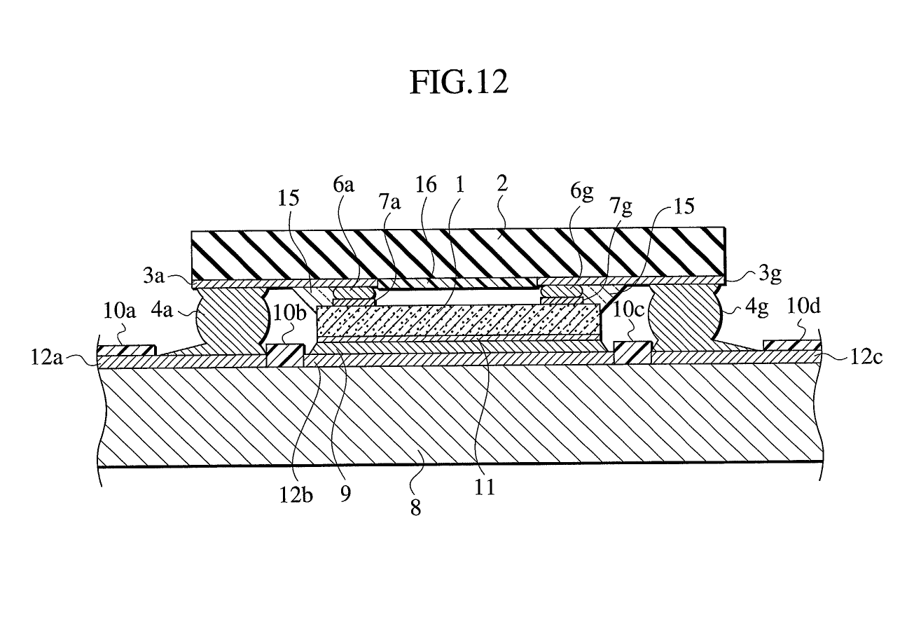

In a semiconductor device according to a fourth embodiment of the present invention shown in FIG. 12, the sealing resin 15 is inserted between a top surface of the semiconductor chip 1 and the first main surface of the module substrate 2, similarly to the semiconductor device of the third embodiment. However, the fourth embodiment is different from the third embodiment in a feature that the sealing resin 15 is disposed selectively to the peripheral region of the semiconductor chip 1 so as not to contact with its active element region (active area). Further, a coat-prevention film 16 is selectively formed as a “coat-control mechanism” on the mounting region of the semiconductor chip 1 near the center of the module substrate 2. This coat-control mechanism is a mechanism configured to prevent the entering (coating) of the sealing resin 15 such that the sealing resin does not contact with the active element region on the top surface of the semiconductor chip 1. The coat-prevention film 16 made of silicone resin or another material, selectively deposited (coated) on the first main surface of the module substrate 2, is employed as the coat-control mechanism, as shown in FIG. 12. Other structure and materials are similar to those already explained in the third embodiment, and the overlapped description or the redundant description is omitted in the forth embodiment.

If the sealing resin 15 is in contact with a transmission line or other passive element (hereafter, “the passive elements” is defined to include the transmission line) on the top surface of the semiconductor chip 1, the dielectric constant on the passive element changes. As the result, the high frequency characteristics such as the characteristic impedance of the passive element changes. If a material having a larger dielectric loss is in contact with the passive element, the high frequency loss such as transmission loss increase. And, if the sealing resin 15 is in contact with the semiconductor active element, a problem such as an increase of the feedback capacitance, ascribable to the capacitance between the gate and the drain, resulting in the reduction of the high frequency gain. Particularly, in the case of a semiconductor element with a planar (lateral) structure in which the source/drain electrodes are nearly exposed to surrounding ambient, such as the high frequency FET, an increase of the feedback capacitance due to the contact of the sealing resin 15 with the source/drain electrodes is remarkable.

By the semiconductor device according to the fourth embodiment as shown in FIG. 12, an excellent high frequency characteristics can be obtained, because the sealing resin 15 is not in contact with the semiconductor active element and/or the passive element including the transmission line disposed in the active element region. Therefore, the inconvenience such as the reduction of the high frequency gain due to the dielectric loss can be eliminated. Further, the stress in the bumps 6a, . . . , 6g, . . . due to the difference in thermal expansion coefficient between the semiconductor chip 1 and the module substrate 2 can be relaxed by inserting the sealing resin 15 between the top surface of the semiconductor chip 1 and the first main surface of the module substrate 2 to be mechanically reinforced. Accordingly, the generation of cracks in the bumps 6a, . . . , 6g, . . . due to various heat treatment required for the assembling processes or to the heat generation associated with the operation of the semiconductor active element after assembling process can be prevented, achieving a high assembling reliability.

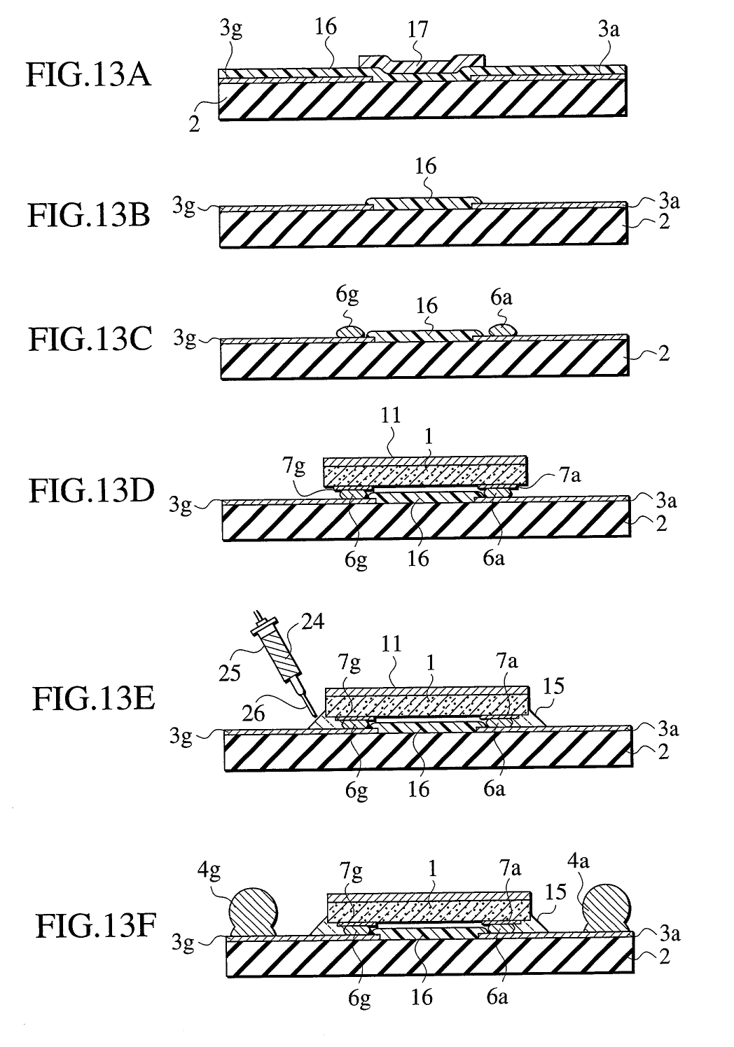

Next, the method of assembling the semiconductor device according to the fourth embodiment will be described using FIGS. 13A to 13F.

(a) First, the module substrate 2, on the first main surface the substrate-cite interconnects 3a, . . . , 3g, . . . are formed, is prepared. Then, the silicone resin is coated as the coat-prevention film 16 over the entire surface of the first main surface containing the substrate-cite interconnects 3a, . . . , 3g, . . . . Further, a photoresist 17 is coated over the entire surface of the silicone resin (coat-prevention film). As shown in FIG. 13A, the photoresist is selectively left only on the central portion of the module substrate 2 which serves as the mounting region for the semiconductor chip 1, by selectively delineating the photoresist 17 using a photolithographic process.

(b) Next, the silicone resin (coat-prevention film) 16 is etched using the photoresist 17 as a mask pattern. As the result, the silicone resin is left selectively as the coat-prevention film 16 on the mounting region for the semiconductor chip 1 in the neighborhood of central portion of the first main surface on the module substrate 2 as shown in FIG. 13B.

(c) The bumps 6a, . . . , 6g, . . . made of gold (Au) are formed in the neighborhood of end portions of the substrate-cite interconnects 3a, . . . , 3g, . . . as shown in FIG. 13C. Further, as shown in FIG. 13D, the semiconductor chip 1 is mounted with the flip chip configuration on the first main surface of the module substrate 2 via the bumps 6a, . . . , 6g, . . . . At this time, the bumps 6a, . . . , 6g, . . . are each made to be connected to the bonding pads 7a, . . . , 7g, . . . arranged on the peripheral region on the top surface of the semiconductor chip 1.

(d) As shown in FIG. 13E, the paste-like resin 24 (or liquid resin) contained in the syringe 25 is caused to flow into the space between the semiconductor chip 1 and the module substrate 2 from the peripheral region of the semiconductor chip 1 by ejecting from the tip of the delivering needle 26 using gas pressure. However, as the coat-prevention film 16 is formed in the mounting region for the semiconductor chip 1 near the central portion of the first main surface, the liquid resin 24 does not flow into the region wherein the coat-prevention film 16 exists. As the result, the liquid resin 24 is selectively coated only on the peripheral region of the semiconductor chip 1 without contact with the active element region on the top surface of the semiconductor chip 1. Then, the sealing resin 15 is formed only in the peripheral region of the semiconductor chip 1, between the semiconductor chip 1 and the module substrate 2.

(e) As shown in FIG. 13F, the ball electrodes 4a, 4b, . . . , 4g, . . . are each formed as the joints in the neighborhood of other end portions of the substrate-cite interconnects 3a, . . . , 3g, . . . . The succeeding process after the state as shown in FIG. 13F is essentially the same as the method of assembling the semiconductor device according to the first embodiment, so that the repeated description will be omitted.

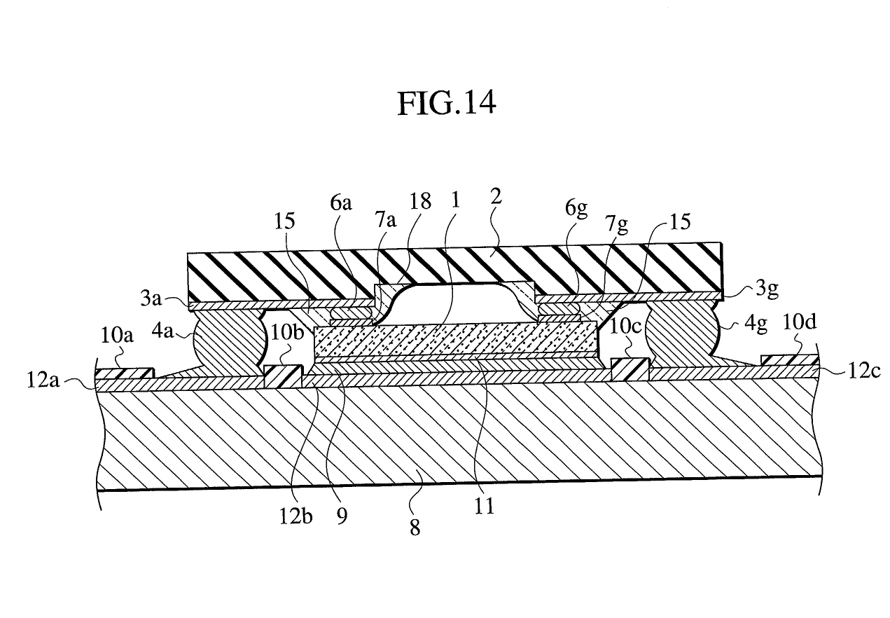

In addition, the “coat-control mechanism” according to the fourth embodiment can employ a mechanism other than the coat-prevention film 16, as long as it can control the coating region of the sealing resin 15. For example, the sealing resin 15 can be coated so as not in contact with the active element on the top surface of the semiconductor chip 1, providing a resin-blocking groove 18 with a given depth on the first main surface of the module substrate 2. It will be shown in FIG. 14 as a modification of the fourth embodiment. If the depth of the resin-blocking groove 18 is made nearly equal to the bump height, i.e. a distance between the peripheral region of the semiconductor chip 1 and the module substrate 2, the entrance of the sealing resin 15 into a direction of the active element region can easily be prevented. When depth of the resin-blocking groove nearly equal to the bump height can be ensured, the sealing resin 15 will not contact with the active element region even if the liquid resin 24 (sealing resin 15) flows into the active element region. Hence, it is effectively equivalent to the prevention of entrance in the direction of the active element region. Therefore, depth of the resin-blocking groove 18 may be established to be about 15 μm to 50 μm.

Further, when the paste-like resin (liquid resin) 24 is coated on the peripheral region of the semiconductor chip 1 in the step shown in FIG. 13E, a liquid-like resin 24 composed of materials with high viscosity in the range from 100 Pa·s to 250 Pa·s at room temperature can be used to prevent the liquid resin 24 from flowing toward the active element region. At this time, clogging of the liquid resin 24 can be avoided when the delivery aperture of the delivering needle 26 of the syringe 25 is made slightly larger, in the range from 0.5 mm to 0.7 mm. And, in such a degree of the delivery aperture, an excess delivering liquid can be prevented and at the same time, drip from the tip of the delivering needle, when delivering is stopped, can be suppressed. Anyway, the “coat-control mechanism” can also be attained by a scheme adopting the paste-like resin (liquid resin) 24 having such a high viscosity.

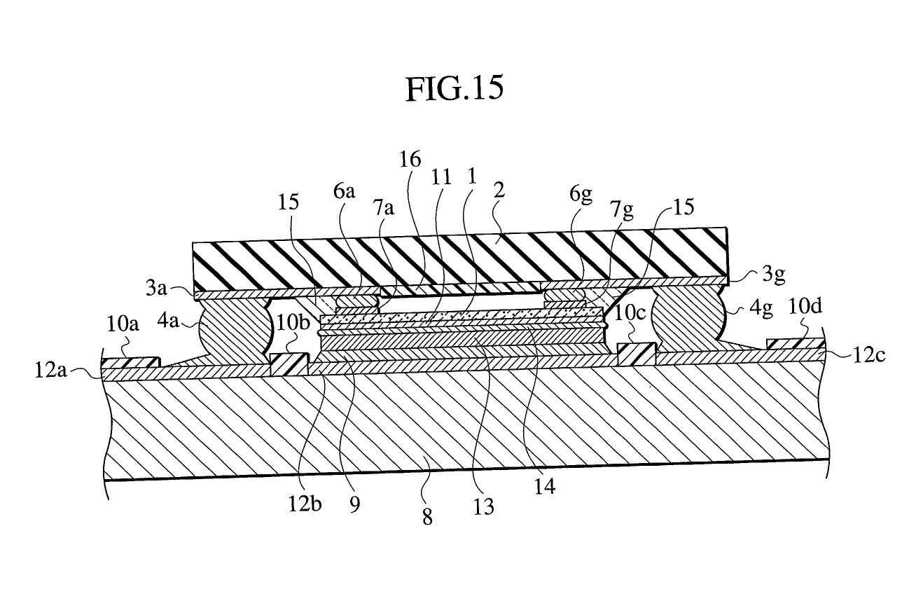

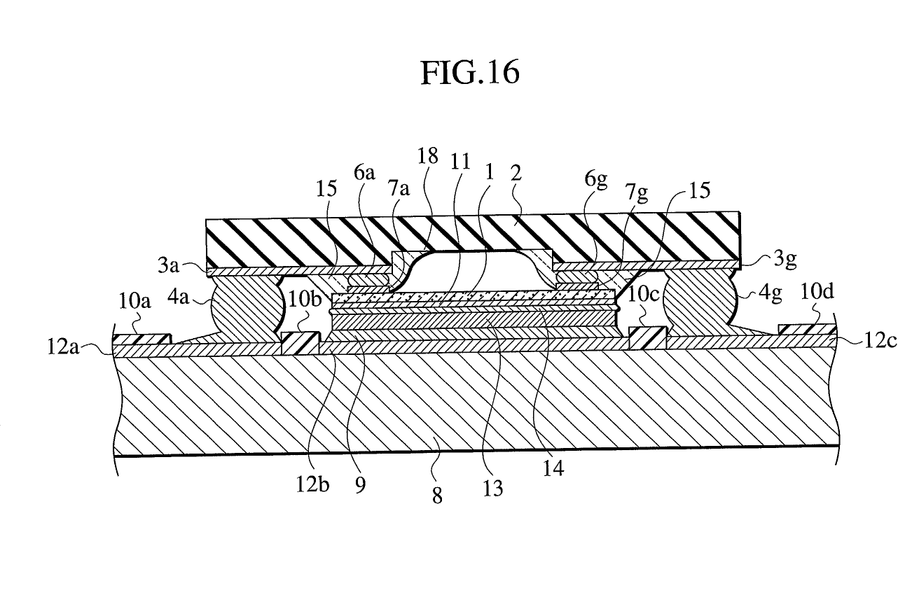

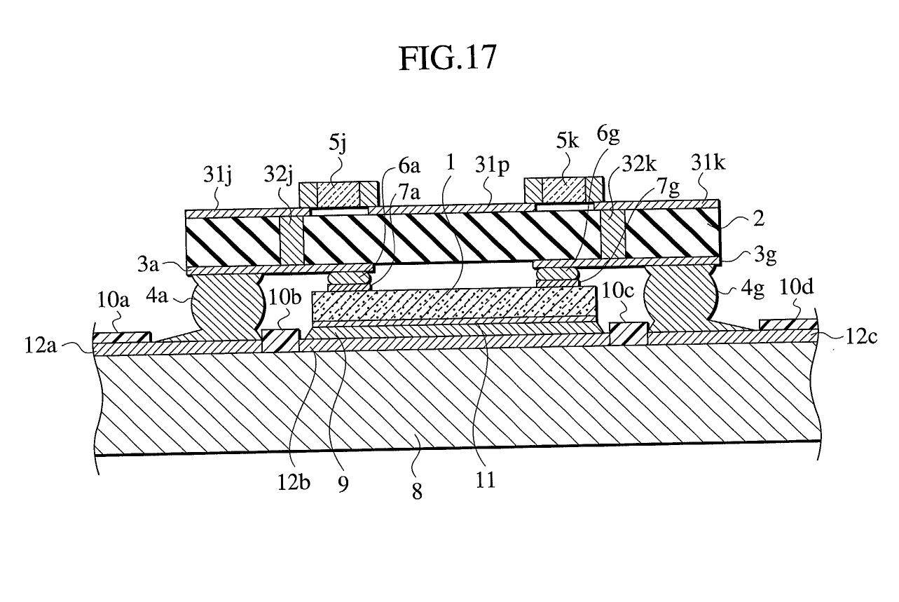

FIGS. 15 and 16 show the structure of the semiconductor device according to other modifications of the fourth embodiment. That is, these are the examples of the structures wherein the sealing resin 15 is prevented from contacting with the active element region on the top surface of the semiconductor chip 1. The structures have the heat conductive plate 13 contacting and sandwiched between the first heat conductive material 9 and the second heat conductive material 14, the first heat conductive material 9 being disposed and contacted with the bottom surface of the semiconductor chip 1, as shown in the third embodiment. In FIG. 15, the coat-prevention film 16 is provided on the mounting region for the semiconductor chip 1 as the “coat-control mechanism”. On the one hand, in FIG. 16 the resin-blocking groove 18 is provided on the mounting region for the semiconductor chip 1 as the “coat-control mechanism”.

By the semiconductor devices according to other modifications of the fourth embodiment shown in FIGS. 15 and 16, the improvement of the heat dissipation by a reduction of the heat resistance is achieved. Further, the effectiveness of preventing the lowering of high frequency characteristics, due to the contact of the sealing resin 15 with the active element region, can be achieved. Further the effectiveness of the relaxing the stress to the bumps 6a, . . . , 6g, . . . , due to the difference in thermal expansion coefficient between the semiconductor chip 1 and the module substrate 2, can be achieved. Further, the effectiveness of maintaining the high mechanical strength and of establishing the effective height of the semiconductor chip 1 in a required level can also be obtained. Hence, a semiconductor device superior in whichever of the high frequency characteristics, the heat dissipating characteristics and the assembling reliability can be provided.

(Fifth Embodiment)

A semiconductor device according to a fifth embodiment of the present invention is different from ones according to the first to fourth embodiments in that the chip-shaped circuit components 5j, 5k, . . . serving as the passive elements such as resistance and capacitor are disposed on the second main surface of the module substrate 2 as shown in FIG. 17. Therefore, in the semiconductor device according to the fifth embodiment, back interconnects 31j, 31k, . . . , 31p, . . . are provided on the second main surface of the module substrate 2. Further, via metals (through hole metals) 32j, 32k, . . . are provided to make electrical connection between the back interconnects 31j, 31k, . . . , 3p, . . . and the substrate-cite interconnects 3a, . . . , 3g, . . . on the first main surface of the module substrate 2. The via metals 32j, 32k, . . . may be metallic plugs perfectly burying the corresponding via holes, or metallic thin films disposed on the sidewall of the corresponding via holes so as to form through holes in each via holes. Further, the module substrate 2 may be a multi-layered substrate in which the inner layer interconnects are buried, though the illustration is omitted (See the interconnect 96 in FIG. 1). The chip-shaped circuit components 5j, 5k, . . . are connected to the back interconnects 31j, 31k, . . . , 31p, . . . using the gold stud bumps, which are the same as those used for mounting the semiconductor chip 1 on the module substrate 2. The back interconnects 31j, 31k, . . . , 31p, . . . (further the inner layer interconnects, as well) can be constituted of wiring material of Ti/Ni/Au similarly to the substrate-cite interconnects 3a, 3b, . . . , 3g, . . . . The via metals 32j, 32k, . . . can also be constituted of metals such as Ti/Ni/Au, W, or Mo. Other structure and materials are similar to those already explained in the first to fourth embodiments, and the overlapped description or the redundant description is omitted in the fifth embodiment. In other words, the structure disposing the chip-shaped circuit components 5j, 5k, . . . on the second main surface of the module substrate 2, according to the fifth embodiment, is applicable to any of the structures of the semiconductor devices according to the first to fourth embodiments already described.

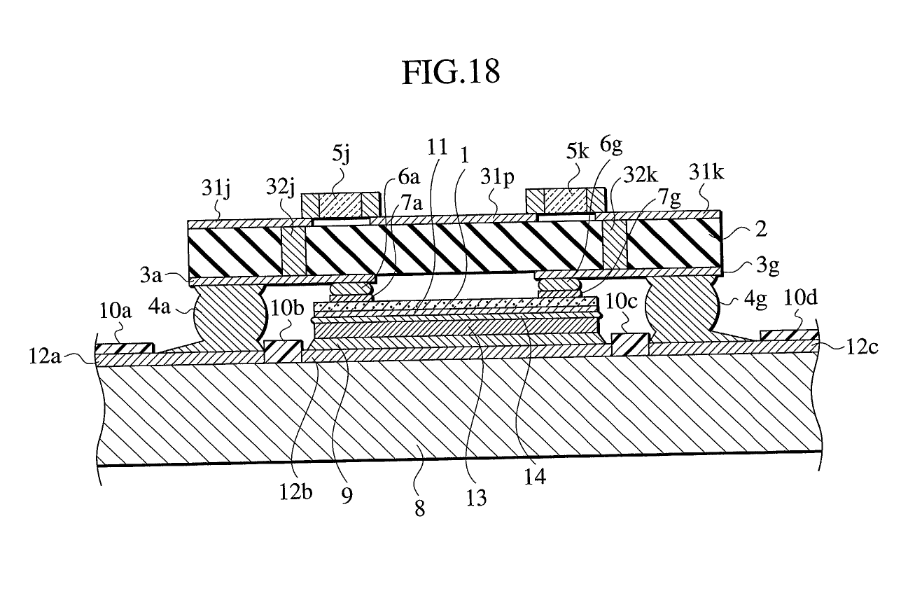

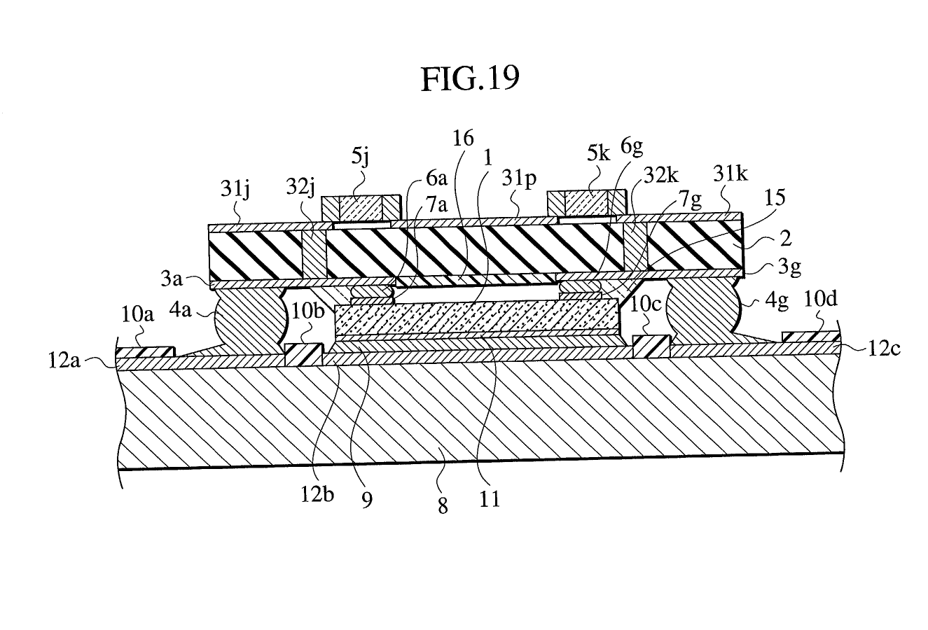

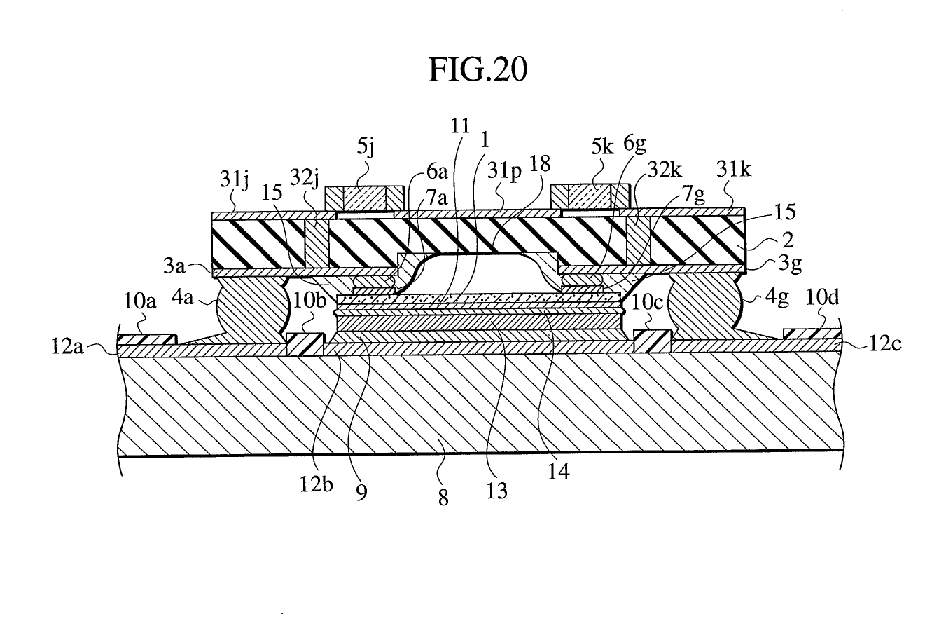

Therefore, the semiconductor device according to the fifth embodiment shown in FIG. 17 corresponds to FIG. 2, illustrated in the first embodiment. And the semiconductor device according to the modification of the fifth embodiment shown in FIG. 18 corresponds to FIG. 6 illustrated in the second embodiment. The semiconductor device according to other modification of the fifth embodiment shown in FIG. 19 corresponds to FIG. 12 illustrated in the fourth embodiment. And the semiconductor device according to further different modification shown in FIG. 20 corresponds to FIG. 16 illustrated in the fourth embodiment.

Therefore, along with the each technical advantages described in the semiconductor device according to the first to first to fourth embodiments, it is capable of adding a new effectiveness of raising the integrated density of circuit components (circuit elements) such as the chip-shaped circuit components, achieving a miniaturized high frequency module.

(Sixth Embodiment)

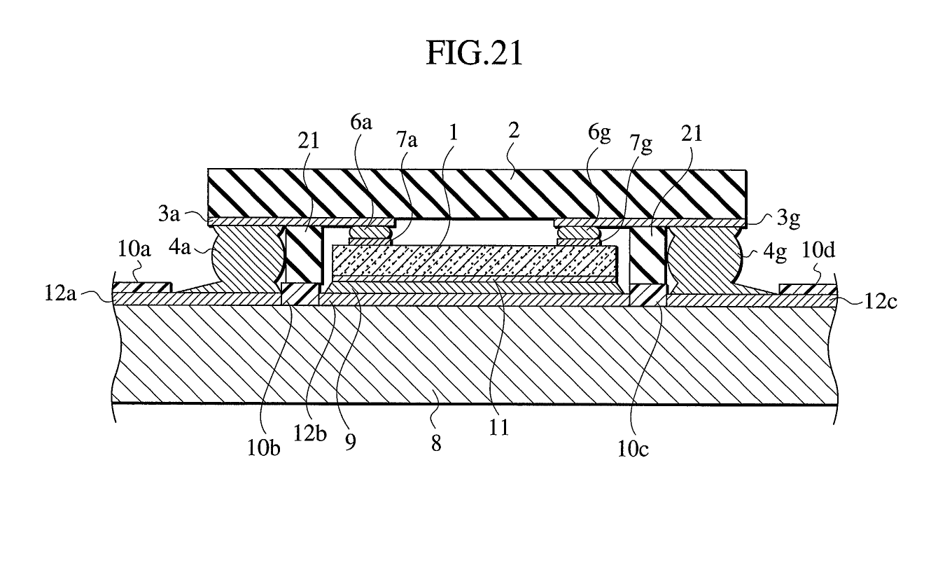

As shown in FIG. 21, a semiconductor device according to a sixth embodiment of the present invention encompasses, similarly to the first embodiment, the module substrate 2, the semiconductor chip 1 mounted on the module substrate 2, and the circuit board 8 mounting the module substrate 2. The substrate-cite interconnects 3a, . . . , 3g, . . . are formed on the first main surface of the module substrate 2. The semiconductor chip 1 is mounted with the flip chip configuration on the module substrate 2 via the substrate-cite interconnects 3a, . . . , 3g, . . . . The ball electrodes, serving as a plurality of joints 4a, . . . , 4g, . . . , are connected with the substrate-cite interconnects 3a, . . . , 3g, . . . . The circuit board 8 has on the top surface a plurality of board-cite interconnects 12a, 12c, . . . , each connecting with a plurality of joints (ball electrodes) 4a, . . . , 4g, . . . . The first heat conductive material 9 thermally connects the bottom surface of the semiconductor chip 1 with the top surface of circuit board 8. In particular, different from the first embodiment, a dielectric spacer 21 is disposed on the module substrate 2. The dielectric spacer 21 has a chip window and a plurality of joint windows. The chip window is a window designed for disposing the semiconductor chip 1. The joint windows are designed for disposing joints 4a, . . . , 4g, . . . . At each bottoms of the joint windows one of end portions of the substrate-cite interconnects 12a, 12c, . . . is exposed. Then, the dielectric spacer 21 surrounds at least a part of the periphery of the ball electrodes 4a, 4b, . . . 4g, . . . and a periphery of the semiconductor chip 1. This dielectric spacer 21 has a thickness substantially equal to that of the semiconductor chip 1.

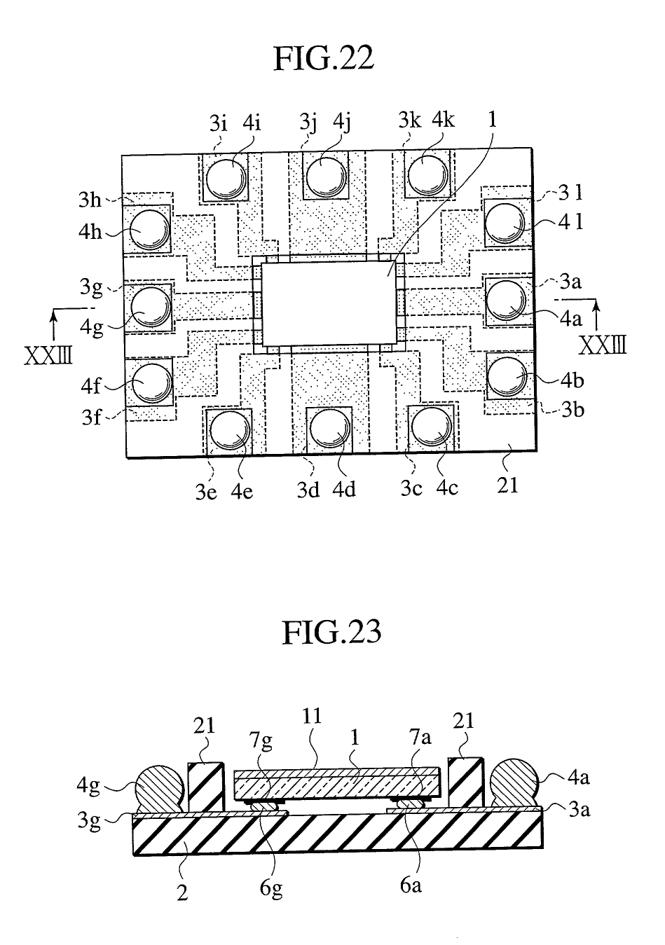

FIG. 22 is a plan view of the high frequency module (module substrate) 2 constituting the semiconductor device according to the sixth embodiment. That is, it shows a plan view of the high frequency module at the state before being mounted on the circuit board 8 as shown in FIG. 21. As shown in FIG. 22, the high frequency module according to the sixth embodiment has the substrate-cite interconnects 3a, 3b, . . . , 3g, . . . shown by broken lines, arranged nearly in a radial manner on the first main surface of the module substrate 2, similarly to the first embodiment. Different from the first embodiment, the dielectric spacer 21 is provided on the substrate-cite interconnects 3a, 3b, . . . , 3g, . . . . The dielectric spacers 21 are disposed surrounding at least a part of peripheries of the ball electrodes 4a, 4b, . . . , 4g, . . . and surrounding the periphery of the semiconductor chip 1 via a required gap. Though the dielectric spacers 21 enclose three surfaces out of four surfaces around the ball electrodes 4a, 4b, . . . , 4g, . . . in FIG. 22, they may enclose all four surfaces to form a closed concave box region. In the plan view of FIG. 22, the patterns of the top surfaces of the substrate-cite interconnects 3a, 3b, . . . , 3g, . . . , exposed in the surrounding gap around the semiconductor chip 1, can be slightly recognized. And the top surfaces of the substrate-cite interconnects 3a, 3b, . . . ,3g, . . . , each exposed on the ball electrode mounting regions, with gaps in the periphery of the bumps 6a, . . . , 6g, can be recognized. Other portions of the substrate-cite interconnects 3a, 3b, . . . , 3g, . . . are hidden under the dielectric spacers 21.

FIG. 23 is a cross sectional view taken on line XXIII-XXIII in FIG. 22, showing that the semiconductor chip 1 is mounted on the first main surface of the module substrate 2 by the flip chip configuration, facing the top surface downward, on which the patterns of the integrated circuits are delineated. The dielectric spacer 21 has the same thickness as the semiconductor chip 1, more accurately the thickness essentially equal to the “effective thickness of the semiconductor chip 1” including the bump height. More definitely, the thickness of the dielectric spacer 21 may be determined taking into account the bump height and the thickness of the first heat conductive material 9.

As shown in the plan view of FIG. 22, the dielectric spacers 21 encloses around the three sides of the ball electrodes 4a and 4g. However, in the cross sectional view shown in FIG. 23, only one side of the dielectric spacer 21 located on the cross section can be seen. That is, the dielectric spacer 21 constitutes a concave box opened towards the edge portion (peripheral region) of the module substrate 2 at the each position of the ball electrodes 4a, . . . , 4g, . . . . Other structure and materials are essentially similar to those already explained in the first embodiment with FIGS. 2 to 4, and the overlapped description or the redundant description is omitted in the sixth embodiment.

When the same material as the module substrate 2 is used as the dielectric spacer 21, the fabrication process becomes easy. For example, if alumina substrate is used as the module substrate 2, the same allumina plate can be used as the dielectric spacer 21. In this case, the structure is considered as a module substrate such that the buried wiring 3a, 3b, . . . , 3g, . . . are inserted between the alumina layer of top surface and that of bottom surface. The alumina layer of top surface serves as the dielectric spacer 21 and that of bottom surface as the module substrate 2. Such a structure can be fabricated simply by firing at high temperature the top and the bottom alumina green sheets simultaneously.

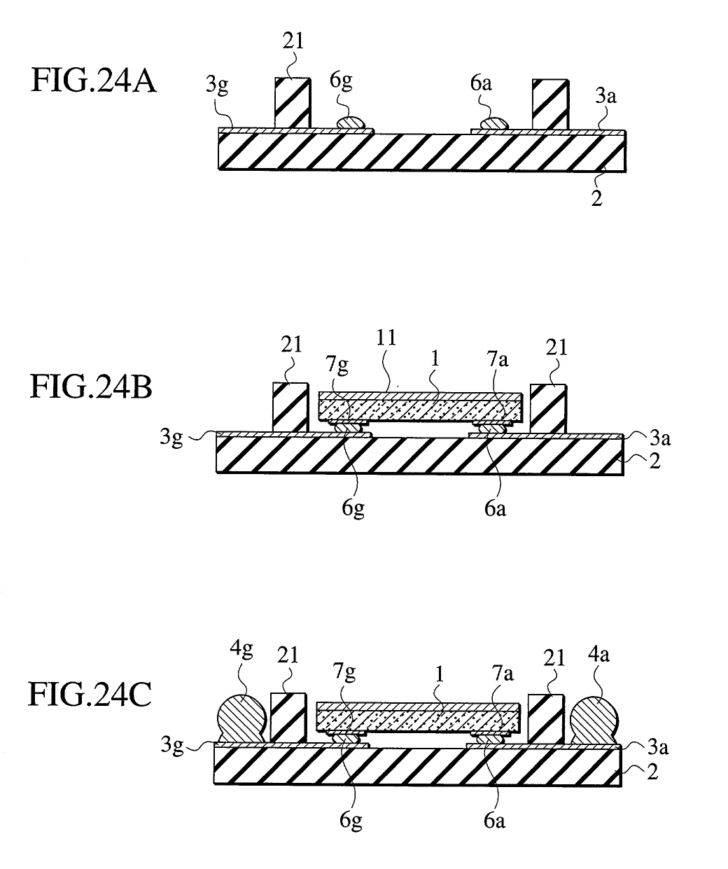

The semiconductor device according to the sixth embodiment of the present invention has a structure wherein the semiconductor chip 1 is contained in the box-type concave portion for the mounting region of the semiconductor chip 1, periphery of which is enclosed by the dielectric spacer 21. As the result, the handling at the assembling process is simplified, as will be clarified in the description of the method of assembling the semiconductor device according to the sixth embodiment, the corresponding cross sectional views for the assembling process are shown in FIGS. 24A to 24C. The solder is caused to reflow after the module substrate 2 is positioned on the circuit board 8. At this time, the distance between the module substrate 2 and the circuit board 8 does not become shorter than the required value because the dielectric spacer 21 serves as a spacer. Further, in the case of mounting the ball electrodes 4a, 4b, . . . , 4g, . . . on the module substrate 2, they can be disposed in the box-like concave regions which become the mounting regions thereof. That is, the mounting step of the ball electrodes 4a, 4b, . . . , 4g, . . . is very simplified because the dielectric spacers 21 serve as a guide.

That is, the semiconductor device according to the sixth embodiment of the present invention can be assembled as follows:

(a) First, the module substrate 2, the substrate-cite interconnects 3a, . . . , 3g, . . . are formed on the first main surface thereof, is prepared. The dielectric spacer 21 has the chip window designed for disposing the semiconductor chip land the joint windows designed for disposing joints 4a, . . . , 4g, . . . . The dielectric spacer 21 is formed on the first main surface, excepting the mounting regions of the semiconductor chip 1 and ball electrodes 4a, 4b, . . . , 4g, . . . . As shown in FIG. 24A, the bumps made of gold 6a, . . . , 6g, . . . are formed in the neighborhood of end portions of the substrate-cite interconnects 3a, . . . , 3g, . . . , all of which are exposed at the chip window, or the mounting region for the semiconductor chip 1.

(b) As shown in FIG. 24B, the semiconductor chip 1 is mounted with the flip chip configuration on the first main surface of the module substrate 2 via the bumps 6a, . . . , 6g, . . . . In this time, when the semiconductor chip 1 is put into the chip window, formed as a box-type concave region, the bumps 6a, . . . , 6g, . . . are automatically aligned and connected to the bonding pads 7a, . . . , 7g, . . . , formed on the peripheral surface of the semiconductor chip 1.

(c) As shown in FIG. 24C, the ball electrodes 4a, 4b, . . . , 4g, . . . are each formed as the joints in the joint window, on each other end potions of the substrate-cite interconnects 3a, . . . , 3g, . . . . In this case, the ball electrodes 4a, 4b, . . . , 4g, . . . are each aligned and put into the joint windows for the ball electrodes, each formed as the box-type concave region. Then the ball electrodes 4a, 4b, . . . , 4g, . . . are automatically aligned and positioned on the top surfaces of the substrate-cite interconnects 3a, 3b, . . . , 3g, . . . exposed on the bottom portion of the joint windows for the ball electrodes. The succeeding steps after the state shown in FIG. 24C are essentially the same as the method of assembling the semiconductor device according to the first embodiment, so that the repeated description will be omitted.

(Other Embodiments)

Various modifications will become possible for those skilled in the art after receiving the teaching of the present disclosure without departing from the scope thereof. For example, though the high frequency module operating at high frequency such as microwave and millimeter wave bands are mainly described in the above first to sixth embodiments, the semiconductor device of the present invention is not limited to those for high frequency. It may be a power semiconductor device or a power IC, composed of the insulating gate bipolar transistor (IGBT) or power MOSFET using semiconductor chip 1 mounted on the module substrate 2. Or, it may be a logic IC and a memory integrated in the semiconductor chip 1 mounted on the module substrate 2. As the semiconductor chip 1, the compound semiconductor material other than the GaAs, or the element semiconductor material such as Si can be used of course.

Thus, the present invention of course includes various embodiments and modifications and the like which are not detailed above. Therefore, the scope of the present invention will be defined in the following claims.

What is claimed is:

1. A semiconductor device comprising:
a module substrate having a first main surface and a second main surface facing with the first main surface;
a plurality of substrate-cite interconnects disposed on the first main surface;
a semiconductor chip having top and bottom surfaces, being mounted with a flip chip configuration, configured such that the top surface of the semiconductor chip facing to the first main surface of said module substrate so as to be aligned with said substrate-cite interconnects;
a plurality of joints connected to said substrate-cite interconnects, respectively;
a circuit board having top and bottom surfaces;
a plurality of board-cite interconnects disposed on the top surface of the circuit board, each being connected to one of said joints; and
a first heat conductive material thermally connecting the bottom surface of said semiconductor chip with the top surface of said circuit board.

2. The semiconductor device of claim 1, further comprising a heat conductive plate in contact with said first heat conductive material.

3. The semiconductor device of claim 2, further comprising a second heat conductive material in contact with said heat conductive plate and connecting thermally said heat conductive plate with the bottom surface of said semiconductor chip.

4. The semiconductor device of claim 1, further comprising an active element region disposed at the top surface of said semiconductor chip and a plurality of bonding pads surrounding the active element region, the bonding pads disposed at the peripheral region on the top surface of said semiconductor chip.

5. The semiconductor device of claim 4, further comprising a plurality of bumps, each of bumps is sandwiched between one of said bonding pads and one of the said substrate-cite interconnects.

6. The semiconductor device of claim 5, further comprising a sealing resin inserted between the top surface of said semiconductor chip and said first main surface of said module substrate.

7. The semiconductor device of claim 6, wherein said sealing resin is selectively disposed on the peripheral region of said semiconductor chip so as not to contact with the active element region.

8. The semiconductor device of claim 7, further comprising a coat-prevention film selectively contacted with the first main surface, disposed just above the active element region.

9. The semiconductor device of claim 7, further comprising a resin-blocking groove, selectively dug at the first main surface, disposed just above the active element region.

10. The semiconductor device of claim 1, further comprising a chip-shaped circuit component disposed on the first main surface.

11. The semiconductor device of claim 1, further comprising a plurality of back interconnects disposed on the second main surface.

12. The semiconductor device of claim 11, further comprising a plurality of via metals, each connecting one of said back interconnects to one of corresponding substrate-cite interconnects.

13. The semiconductor device of claim 12, further comprising a chip-shaped circuit component disposed on the second main surface, being configured to connect with one of said back interconnects.

14. The semiconductor device of claim 1, further comprising a dielectric spacer disposed on the first main surface, the dielectric spacer having substantially same thickness as that of said semiconductor chip, enclosing said semiconductor chip and at least partly said joint.

15. The semiconductor device of claim 14, wherein said substrate-cite interconnects are sandwiched between said dielectric spacer and the first main surface.

16. A method of assembling a semiconductor device, comprising:
preparing a module substrate having the first main surface and the second main surface facing to said first main surface, a plurality of substrate-cite interconnects being formed on said first main surface;
forming bumps on each of end portions of said substrate-cite interconnects;
mounting a semiconductor chip by a flip chip configuration, facing a top surface thereof to said first main surface, configured such that bonding pads disposed on the top surface of the semiconductor chip contact respectively with said bumps;
forming a plurality of joints on other end portions of said substrate-cite interconnects, respectively; and
mounting said module substrate on a circuit board, configured such that said joints connect to corresponding board-cite interconnects disposed on a top surface of the circuit board, and thermally connecting a bottom surface of said semiconductor chip with the top surface of said circuit board.

17. The method of claim 16, further comprising inserting a sealing resin selectively between the peripheral region of said semiconductor chip and the first main surface, configured such that the sealing resin does not contact with an active element region on the top surface of said semiconductor chip.

18. The method of claim 17, further comprising delineating a coat-prevention film on the first main surface before said mounting.

19. The method of claim 16, further comprising forming a dielectric spacer on the first main surface, the dielectric spacer having a chip window designed for disposing said semiconductor chip and a plurality of joint windows designed for disposing said joints, configured such that at each bottoms of the joint windows one of said end portions of said substrate-cite interconnects is exposed.

20. The method of claim 19, wherein said mounting mounts said semiconductor chip in the chip window, and said forming automatically aligns and positions a plurality of ball electrodes serving as said joints in respective joint windows.
